(19) United States
(12) Patent Application Publication
(10) Pub. No.: US 2024/0222503 A1
(43) Pub. Date: Jul. 4, 2024

(54) SEMICONDUCTOR DEVICE AND METHOD FOR FABRICATING THE SAME

(71) Applicant: SK hynix Inc., Gyeonggi-do (KR)

(72) Inventors: Seung Hwan KIM, Gyeonggi-do (KR); Jun Ha KWAK, Gyeonggi-do (KR); Jin Sun CHO, Gyeonggi-do (KR)

(21) Appl. No.: 18/350,747

(22) Filed: Jul. 12, 2023

(30) Foreign Application Priority Data
Dec. 30, 2022 (KR) 10-2022-0190597

(51) Int. Cl. H01L 29/78; H10B 12/00

(52) U.S. Cl. CPC H01L 29/7831; H10B 12/482

(57) ABSTRACT

A semiconductor device includes: a horizontal layer spaced apart from a lower structure and extending in a direction parallel to the lower structure; a vertical conductive line extending in a direction perpendicular to the lower structure and coupled to one end of the horizontal layer; a data storage element coupled to another end of the horizontal layer; and a horizontal conductive line extending in a direction crossing the horizontal layer, wherein the horizontal conductive line includes: a first work function electrode; a second work function electrode adjacent to the vertical conductive line and having a lower work function than the first work function electrode; a third work function electrode having a lower work function than the first work function electrode; a first barrier layer between the first and third work function electrodes; and a second barrier layer between the first and second work function electrode.

### CROSS-REFERENCE TO RELATED APPLICATIONS

The present application claims priority of Korean Patent Application No. 10-2022-0190597, filed on Dec. 30, 2022, which is incorporated herein by reference in its entirety.

### BACKGROUND

### 1. Field

Various embodiments of the present invention relate to a semiconductor device, and more particularly, to a semiconductor device including memory cells that are arranged in three dimensions, and a method for fabricating the same.

### 2. Description of the Related Art

To satisfy the recent demands for large capacity and miniaturization of memory devices, three-dimensional memory devices including memory cells that are stacked in three dimensions have been advanced.

### SUMMARY

Embodiments of the present invention are directed to a semiconductor device including highly integrated memory cells, and a method for fabricating the semiconductor device.

In accordance with one embodiment of the present invention, a semiconductor device includes: a lower structure; a horizontal layer spaced apart from the lower structure and extending in a direction parallel to the lower structure; a vertical conductive line extending in a direction perpendicular to the lower structure and coupled to a first-side end of the horizontal layer; a data storage element coupled to a second-side end of the horizontal layer; and a horizontal conductive line extending in a direction crossing the horizontal layer, wherein the horizontal conductive line includes: a first work function electrode; a second work function electrode disposed adjacent to the vertical conductive line and having a lower work function than the first work function electrode; a third work function electrode disposed adjacent to the data storage element and having a lower work function than the first work function electrode; a first barrier layer between the first work function electrode and the third work function electrode; and a second barrier layer between the first work function electrode and the second work function electrode.

In accordance with another embodiment of the present invention, a method for fabricating a semiconductor device includes: forming a stack body in which a dielectric layer, a first sacrificial layer, a semiconductor layer, and a second sacrificial layer are alternately stacked over a lower structure; forming an opening by etching the stack body; forming horizontal recesses by recessing the first and second sacrificial layers from the opening; and forming a horizontal conductive line including a combination of different work function electrodes in the horizontal recesses, wherein the forming of the horizontal conductive line includes: forming a first low work function electrode; forming a first barrier layer over the first low work function electrode; forming a high work function electrode having a higher work function than the first low work function electrode over the first barrier layer;

forming a second barrier layer over the high work function electrode; and forming a second low work function electrode having a lower work function than the high work function electrode over the second barrier layer. Each of the first and second low work function electrodes includes doped polysilicon that is doped with an N-type dopant. The high work function electrode includes a metal-based material. The first and second barrier layers include a metal nitride. The method further include: after the forming of the horizontal conductive line, forming a vertical conductive line filling the opening; and forming a data storage element coupled to a second-side end of the horizontal layer.

In accordance with still another embodiment of the present invention, a semiconductor device includes, a semiconductor layer spaced apart from a lower structure and extending in a direction parallel to the lower structure; a vertical conductive line extending in a direction perpendicular to the substrate and coupled to a first-side end of the semiconductor layer; a data storage element coupled to a second-side end of the semiconductor layer; and a word line extending in a direction crossing the semiconductor layer, wherein the word line includes: a metal electrode; a first polysilicon electrode disposed adjacent to the vertical conductive line and having a lower work function than the metal electrode; and a second polysilicon electrode disposed adjacent to the data storage element and having a lower work function than the metal electrode.

In accordance with yet another embodiment of the present invention, a semiconductor device includes: a lower structure; a three-dimensional array including a column array of vertically stacked transistors over the lower structure; a vertical conductive line oriented vertically over the lower structure and commonly coupled to first sides of the transistors of the three-dimensional array; and a data storage element coupled to second sides of the transistors of the three-dimensional array, wherein the transistors of the column arrays of the three-dimensional array includes: a horizontal layer; and a horizontal conductive line having a triple work function electrode structure extending horizontally in a direction crossing the horizontal layer. The horizontal conductive line of the triple work function electrode structure may include a first low work function electrode, a second low work function electrode, and a high work function electrode between the first low work function electrode and the second low work function electrode.

### BRIEF DESCRIPTION OF THE DRAWINGS

FIG. 1A is a schematic perspective view illustrating a memory cell in accordance with one embodiment of the present invention.

FIG. 1B is a schematic cross-sectional view illustrating the memory cell of FIG. 1A.

FIG. 2A is a schematic plan view illustrating a memory cell array.

FIG. 2B is a cross-sectional view taken along a line A-A′ of FIG. 1.

FIG. 3 is a schematic cross-sectional view illustrating a semiconductor device in accordance with another embodiment of the present invention.

FIG. 4 is a schematic cross-sectional view illustrating a semiconductor device in accordance with still another embodiment of the present invention.

FIGS. 5 to 24 illustrate an example of a method for fabricating a semiconductor device in accordance with yet another embodiment of the present invention.

### DETAILED DESCRIPTION

Various embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

According to the following embodiments of the present invention described below, memory cells may be vertically stacked to increase memory cell density and reduce parasitic capacitance.

The following embodiments of the present invention described below relate to three-dimensional memory cells, and a horizontal conductive line (which is a word line or a gate electrode) may include a low work function electrode and a high work function electrode. The low work function electrode may be disposed adjacent to a data storage element (e.g., a capacitor) and a vertical conductive line (or bit line), and the high work function electrode may overlap with a channel of the horizontal layer.

Due to the low work function of the low work function electrode, a low electric field may be formed between the horizontal conductive line and the data storage element, thereby reducing leakage current.

A high work function of a high work function electrode may not only form a high threshold voltage of a switching element, but also may form a low electric field, which allows the height of a memory cell to be reduced. This is advantageous in terms of device integration.

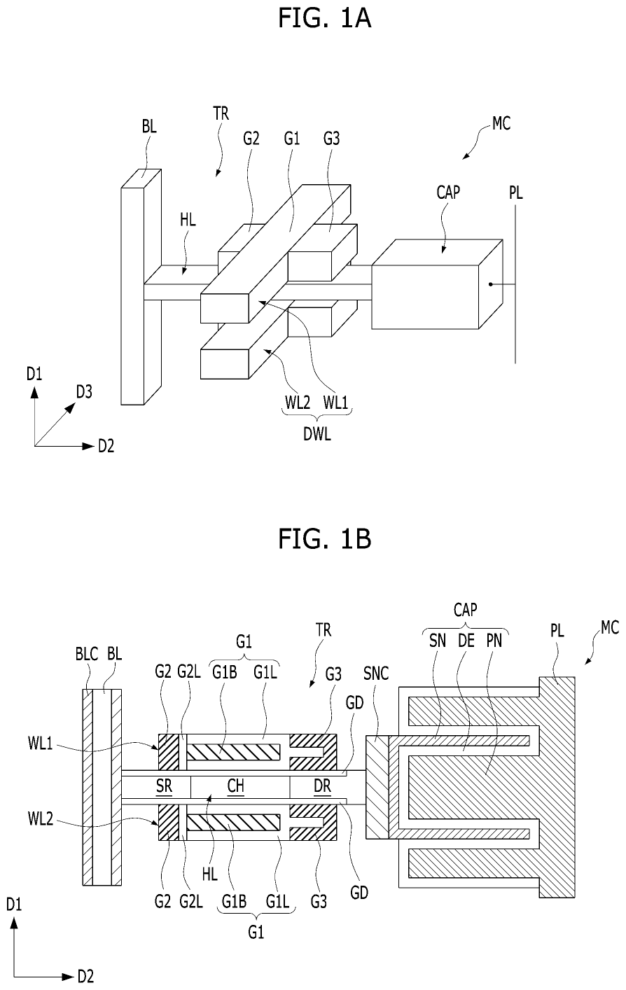

FIG. 1A is a schematic perspective view illustrating a memory cell in accordance with one embodiment of the present invention. FIG. 1B is a schematic cross-sectional view illustrating the memory cell of FIG. 1A.

Referring to FIGS. 1A and 1B, a memory cell MC may include a vertical conductive line BL, a switching element TR, and a data storage element CAP. The switching element TR may include a horizontal layer HL, a gate dielectric layer GD, and a horizontal conductive line DWL. The data storage element CAP may include a memory element, such as a capacitor. The vertical conductive line BL may include a bit line. The horizontal conductive line DWL may include a word line, and the horizontal layer HL may include an active layer. The data storage element CAP may include a first electrode SN, a dielectric layer DE, and a second electrode PN. The switching element TR may include a transistor, and in this case, the horizontal conductive line DWL may serve as a gate electrode. The switching element TR may also be referred to as an access element or a selection element.

The vertical conductive line BL may extend vertically in a first direction D1. The horizontal layer HL may extend in a second direction D2 crossing the first direction D1. The horizontal conductive line DWL may extend in a third direction D3 crossing the first and second directions D1 and D2. The first direction D1 may be a vertical direction, the second direction D2 may be a first horizontal direction, and the third direction D3 may be a second horizontal direction.

The vertical conductive line BL may be vertically oriented in the first direction D1. The vertical conductive line BL may be referred to as a vertically-oriented bit line, a vertically-extended bit line, or a pillar-shaped bit line. The vertical conductive line BL may include a conductive material. The vertical conductive line BL may include a silicon-based material, a metal-based material, or a combination thereof. The vertical conductive line BL may include for example polysilicon, a metal, a metal nitride, a metal silicide, or a combination thereof. The vertical conductive line BL may include for example polysilicon, titanium nitride, tungsten, or a combination thereof. In one example, the vertical conductive line BL may include polysilicon or titanium nitride (TiN) which is doped with an N-type impurity. The vertical conductive line BL may include a stack (TiN/W) of titanium nitride and tungsten.

The switching element TR may include a transistor, and thus, the horizontal conductive line DWL may be referred to as a horizontal gate line or a horizontal word line.

The horizontal conductive line DWL may extend in the third direction D3, and the horizontal layer HL may extend in the second direction D2. The horizontal layer HL may be horizontally arranged from the vertical conductive line BL. The horizontal conductive line DWL may have a double structure. For example, the horizontal conductive line DWL may include first and second horizontal conductive lines WL1 and WL2 that are facing each other with the horizontal layer HL interposed therebetween. A gate dielectric layer GD may be formed on the upper and lower surfaces of the horizontal layer HL. The first horizontal conductive line WL1 may be disposed over the horizontal layer HL, and the second horizontal conductive line WL2 may be disposed below the horizontal layer HL. The horizontal conductive line DWL may include a pair of a first horizontal conductive line WL1 and a second horizontal conductive line WL2. In the horizontal conductive line DWL, the first horizontal conductive line WL1 and the second horizontal conductive line WL2 may have the same potential. For example, the first horizontal conductive line WL1 and the second horizontal conductive line WL2 may form a pair to be coupled to one memory cell MC. The same driving voltage (or different driving voltages) may be applied to the first horizontal conductive line WL1 and the second horizontal conductive line WL2.

The horizontal layer HL may extend in the second direction D2. The horizontal layer HL may include a semiconductor material. For example, the horizontal layer HL may include for example polysilicon, monocrystalline silicon, germanium, or silicon-germanium. According to another embodiment of the present invention, the horizontal layer HL may include an oxide semiconductor material. In one example, the oxide semiconductor material may include indium gallium zinc oxide (IGZO).

The upper and lower surfaces of the horizontal layer HL may have flat surfaces. In other words, the upper and lower surfaces of the horizontal layer HL may be parallel to each other in the second direction D2.

The horizontal layer HL may include a channel CH, a first doped region SR between the channel CH and the vertical conductive line BL, and a second doped region DR between the channel CH and the data storage element CAP. When the horizontal layer HL is formed of an oxide semiconductor material, the channel CH may be formed of an oxide semiconductor material, and the first and second doped regions SR and DR may be omitted. The horizontal layer HL may also be referred to as an active layer or a thin-body.

The first doped region SR and the second doped region DR may be doped with impurities of the same conductivity type. The first doped region SR and the second doped region DR may be doped with an N-type impurity or a P-type impurity. The first doped region SR and the second doped region DR may for example include at least one impurity selected among arsenic (As), phosphorus (P), boron (B), indium (In), and combinations thereof. The first doped region SR may be coupled to the vertical conductive line BL, and the second doped region DR may be coupled to a first electrode SN of the data storage element CAP. The first doped region SR and the second doped region DR may be referred to respectively as a first second source/drain region and a second source/drain region.

The gate dielectric layer GD may include for example silicon oxide, silicon nitride, a metal oxide, a metal oxide nitride, a metal silicate, a high-k material, a ferroelectric material, an antiferroelectric material, or a combination thereof. The gate dielectric layer GD may include for example SiO₂, Si₃N₄, HfO₂, Al₂O₃, ZrO₂, AION, HfON, HfSiO, HfSiON, or a combination thereof.

The horizontal conductive line DWL may include a metal, a metal mixture, a metal alloy, or a semiconductor material. The horizontal conductive line DWL may include for example titanium nitride, tungsten, polysilicon, or a combination thereof. In one example, the horizontal conductive line DWL may include a TiN/W stack in which titanium nitride and tungsten are sequentially stacked. The horizontal conductive line DWL may include an N-type work function material or a P-type work function material. The N-type work function material may have a low work function of approximately 4.5 eV or less, and the P-type work function material may have a high work function of approximately 4.5 eV or more.

Each of the first and second horizontal conductive lines WL1 and WL2 may include a first work function electrode G1, a second work function electrode G2, and a third work function electrode G3. The first work function electrode G1, the second work function electrode G2, and the third work function electrode G3 may be horizontally disposed in the second direction D2. The first work function electrode G1, the second work function electrode G2, and the third work function electrode G3 may be parallel to each other while directly contacting each other. The second work function electrode G2 may be disposed adjacent to (or otherwise between the first work function electrode G1 and) the vertical conductive line BL, and the third work function electrode G3 may be disposed adjacent to (or otherwise between the first work function electrode G1 and) the data storage element CAP. The horizontal layer HL may have a thickness which is smaller than the thicknesses of the first, second, and third work function electrodes G1, G2, and G3.

In one embodiment, the first work function electrode G1, the second work function electrode G2, and the third work function electrode G3 may be formed of different work function materials, although second work function electrode G2 and third work function electrode G3 may be formed from the same work function material. The first work function electrode G1 may have a higher work function than the second and third work function electrodes G2 and G3. The first work function electrode G1 may include a high work function material. The first work function electrode G1 may have a work function which is higher than a mid-gap work function of silicon. The second and third work function electrodes G2 and G3 may include a low work function material. The second and third work function electrodes G2 and G3 may have a work function which is lower than a mid-gap work function of silicon. In other words, the high work function material may have a work function which is higher than approximately 4.5 eV, and the low work function material may have a work function which is lower than approximately 4.5 eV. The first work function electrode G1 may include a metal-based material, and the second and third work function electrodes G2 and G3 may include a semiconductor material.

The second and third work function electrodes G2 and G3 may include doped polysilicon that is doped with an N-type dopant. The first work function electrode G1 may include a metal, a metal nitride, or a combination thereof. The first work function electrode G1 may include for example tungsten, titanium nitride, or a combination thereof. A barrier material may be further formed between the second and third work function electrodes G2 and G3 and the first work function electrode G1.

According to one embodiment of the present invention, each of the first and second horizontal conductive lines WL1 and WL2 of the horizontal conductive line DWL may include a second work function electrode G2, a first work function electrode G1, a third work function electrode G3 that are horizontally arranged in the mentioned order in the second direction D2. The first work function electrode G1 may include a metal, and the second work function electrode G2 and the third work function electrode G3 may include polysilicon.

In another embodiment, each of the first and second horizontal conductive lines WL1 and WL2 of the horizontal conductive line DWL may have a PMP (Polysilicon-Metal-Polysilicon) structure that is horizontally arranged in the second direction D2. In the PMP structure, the first work function electrode G1 may be a metal-based material, and the second and third work function electrodes G2 and G3 may be doped polysilicon which is doped with an N-type dopant. The N-type dopant may include phosphorus or arsenic.

The first work function electrode G1 may include a stack in which a first barrier layer G1L and a bulk layer G1B are sequentially stacked. The first barrier layer G1L may include for example titanium nitride, tantalum nitride, tungsten nitride, or molybdenum nitride. The bulk layer G1B may include for example tungsten, molybdenum, or aluminum. In one example, the first work function electrode G1 may include a ‘titanium nitride/tungsten (TiN/W) stack’. The titanium nitride (TiN) may correspond to the first barrier layer G1L, and tungsten (W) may correspond to the bulk layer G1B.

In one embodiment, the first work function electrode G1 may have a greater volume than the second and third work function electrodes G2 and G3, and accordingly, the horizontal conductive line DWL may have a low resistance. The first work function electrodes G1 of the first and second horizontal conductive lines WL1 and WL2 may vertically overlap with each other in the first direction D1 with the horizontal layer HL interposed therebetween. The second and third work function electrodes G2 and G3 of the first and second horizontal conductive lines WL1 and WL2 may vertically overlap with each other in the first direction D1 with the horizontal layer HL interposed between the first and second horizontal conductive lines WL1 and WL2. The overlapping area between the first work function electrode G1 and the horizontal layer HL may be greater than the overlapping area between the second and third work function electrodes G2 and G3 and the horizontal layer HL. The second and third work function electrodes G2 and G3 and the first work function electrode G1 may extend in the third direction D3.

The horizontal conductive line DWL may further include a second barrier layer G2L which is disposed between the first work function electrode G1 and the second work function electrode G2. The second barrier layer G2L may include for example titanium nitride, tantalum nitride, tungsten nitride, or molybdenum nitride.

The third work function electrode G3 may have a bent shape or a cup shape. The third work function electrode G3 may include an inner surface covering the first barrier layer G1L, and an outer surface contacting the first electrode SN. The third work function electrode G3 may include a bent low work function material. The first barrier layer G1L may surround a portion of the bulk layer G1B. The first barrier layer G1L may have a bent shape or a cup shape. The first barrier layer G1L may include an inner surface covering the bulk layer G1B, and an outer surface contacting the third work function electrode G3. The first barrier layer G1L may have a protruding shape filling the inner surface of the first work function electrode G1 (as shown for example in FIG. 1B). The second barrier layer G2L may have a vertical or flat shape (as shown for example in FIG. 1B).

As described above, each of the first and second horizontal conductive lines WL1 and WL2 may have a triple electrode structure including first, second, and third work function electrodes G1, G2, and G3. The horizontal conductive line DWL may include a pair of first work function electrodes G1, a pair of second work function electrodes G2, and a pair of third work function electrodes G3 extending in the third direction D3 crossing the horizontal layer HL with the horizontal layer HL interposed therebetween. The first work function electrodes G1 of the horizontal conductive line DWL may vertically overlap with the channel CH, and the second work function electrodes G2 of the horizontal conductive line DWL may vertically overlap with the first doped region SR of the horizontal layer HL, and the third work function electrodes G3 of the horizontal conductive line DWL may vertically overlap with the second doped region DR of the horizontal layer HL.

The first work function electrode G1 of a high work function may be disposed at the center of the horizontal conductive line DWL, and as the second and third work function electrodes G2 and G3 of a low work function are disposed at both ends of the horizontal conductive line DWL, leakage current such as gate induced drain leakage (GIDL) may be improved.

As the first work function electrode G1 of a high work function is disposed at the center of the horizontal conductive line DWL, the threshold voltage of the switching element TR may be increased. Since the second work function electrode G2 of the horizontal conductive line DWL has a low work function, a low electric field may be formed between the vertical conductive line BL and the horizontal conductive line DWL. Since the third work function electrode G3 of the horizontal conductive line DWL has a low work function, a low electric field may be formed between the data storage element CAP and the horizontal conductive line DWL.

The data storage element CAP may be horizontally disposed in the second direction D2 from the switching element TR. The data storage element CAP may include a first electrode SN extending horizontally from the horizontal layer HL in the second direction D2. The data storage element CAP may further include a second electrode PN over the first electrode SN, and a dielectric layer DE between the first electrode SN and the second electrode PN. The first electrode SN, the dielectric layer DE, and the second electrode PN may be horizontally arranged in the second direction D2. The first electrode SN may have a horizontally oriented cylindrical-shape. The dielectric layer DE may conformally cover the inner wall and the outer wall of the cylinder of the first electrode SN. The second electrode PN may cover the cylindrical inner wall and a cylindrical outer wall of the first electrode SN over the dielectric layer DE. The first electrode SN may be electrically connected to the second source/drain region DR.

The first electrode SN may have a 3D structure, and the first electrode SN of the 3D structure may have a 3D structure that is horizontally oriented in the second direction D2. As an example of a 3D structure, the first electrode SN may have a cylindrical shape. According to another embodiment of the present invention, the first electrode SN may have a pillar shape or a pylinder shape. The pylinder shape may refer to a structure in which a pillar shape and a cylindrical shape are merged.

The first electrode SN and the second electrode PN may include a metal, a noble metal, a metal nitride, a conductive metal oxide, a conductive noble metal oxide, a metal carbide, a metal silicide, or a combination thereof. In one embodiment, the first electrode SN and the second electrode PN may include for example titanium (Ti), titanium nitride (TiN), tantalum (Ta), tantalum nitride (TaN), tungsten (W), or tungsten nitride (WN)., ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack or a combination thereof. The second electrode PN may include a combination of a metal-based material and a silicon-based material. In one example, the second electrode PN may be a stack of titanium nitride/silicon germanium/tungsten nitride (TiN/SiGe/WN). In the titanium nitride/silicon germanium/tungsten nitride (TiN/SiGe/WN) stack, silicon germanium may be a gap-fill material filling the cylindrical inside of the first electrode SN, and titanium nitride (TIN) may serve as the second electrode PN of the data storage element CAP, and tungsten nitride may be a low-resistance material.

The dielectric layer DE may be referred to as a capacitor dielectric layer or a memory layer. The dielectric layer DE may include silicon oxide, silicon nitride, a high-k material, or a combination thereof. The high-k material may have a higher dielectric constant than silicon oxide. Silicon oxide (SiO₂) may have a dielectric constant of approximately 3.9, and the dielectric layer DE may include a high-k material having a dielectric constant of approximately 4 or more. In one embodiment, the high-k material may have a dielectric constant of approximately 20 or greater. The high-k material may include for example hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅) or strontium titanium oxide (SrTiO₃). According to another embodiment of the present invention, the dielectric layer DE may be formed of a composite layer including two or more layers of the aforementioned high-k materials.

The dielectric layer DE may be formed of zirconium (Zr)-based oxide. The dielectric layer DE may have a stack structure including zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked over zirconium oxide (ZrO₂). The ZAZ stack may have a structure in which zirconium oxide (ZrO₂), aluminum oxide (Al₂O₃), and zirconium oxide (ZrO₂) are sequentially stacked. Either of the ZA stack and the ZAZ stack may be referred to as a zirconium oxide (ZrO₂)-based layer. According to another embodiment of the present invention, the dielectric layer DE may be formed of hafnium (Hf)-based oxide. The dielectric layer DE may have a stack structure including hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked over hafnium oxide (HfO₂). The HAH stack may have a structure in which hafnium oxide (HfO₂), aluminum oxide (Al₂O₃), and hafnium oxide (HfO₂) are sequentially stacked. Either of the HA stack and the HAH stack may be referred to as a hafnium oxide (HfO₂)-based layer. In the ZA stack, the ZAZ stack, the HA stack, and the HAH stack, the aluminum oxide (Al₂O₃) may have a greater bandgap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high-bandgap material having a greater bandgap than the high-k material. The dielectric layer DE may include silicon oxide (SiO₂) as a high bandgap material other than aluminum oxide (Al₂O₃). Since the dielectric layer DE includes a high bandgap material, leakage current may be suppressed. The high-bandgap material may be thinner than the high-k material. According to another embodiment of the present invention, the dielectric layer DE may include a laminated structure in which a high-k material and a high-bandgap material are alternately stacked. In one example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, or a HAHAH (HfO₂/Al₂O₃/HfO₂/Al₂O₃/HfO₂) stack. In the above laminated structure, aluminum oxide (Al₂O₃) may be thinner than zirconium oxide (ZrO₂) and hafnium oxide (HfO₂).

According to another embodiment of the present invention, the dielectric layer DE may include a stack structure, a laminated structure, or a mixed structure including zirconium oxide, hafnium oxide, and aluminum oxide.

According to another embodiment of the present invention, an interface control layer for improving leakage current may be further formed between the first electrode SN and the dielectric layer DE. The interface control layer may include for example titanium oxide (TiO₂), tantalum oxide (Ta₂O₅), or niobium oxide (Nb₂O₅). The interface control layer may also be formed between the second electrode PN and the dielectric layer DE.

The data storage element CAP may include a Metal-Insulator-Metal (MIM) capacitor. The first electrode SN and the second electrode PN may include a metal-based material.

The data storage element CAP may be replaced with other data storage materials. For example, the data storage material may be a phase change material, a magnetic tunnel junction (MTJ), or a variable resistance material.

As described above, the memory cell MC may include the horizontal conductive line DWL having a triple work function electrode structure. Each of the first and second horizontal conductive lines WL1 and WL2 of the horizontal conductive line DWL may include a first work function electrode G1, a second work function electrode G2, and a third work function electrode G3. The first work function electrode G1 may overlap with the channel CH, and the second work function electrode G2 may be disposed adjacent to (or otherwise between the first work function electrode G1 and) the vertical conductive line BL and the first doped region SR, and the third work function electrode G3 may be disposed adjacent to (or otherwise between the first work function electrode G1 and) the data storage element CAP and the second doped region DR. Due to a low work function of the second work function electrode G2, a low electric field may be formed between the horizontal conductive line DWL and the vertical conductive line BL, thereby reducing leakage current. Also, due to a low work function of the third work function electrode G3, a low electric field may be formed between the horizontal conductive line DWL and the data storage element CAP, thereby improving leakage current. Due to a high work function of the first work function electrode G1, not only a high threshold voltage of the switching element TR may be formed, but also the height of the memory cell MC may be reduced due to the formation of a low electric field, which is advantageous in terms of device integration.

As Comparative Example 1, when the first and second horizontal conductive lines WL1 and WL2 are formed of a metal-based material alone, due to a high work function of the metal-based material, a high electric field may be formed between the first and second horizontal conductive lines WL1 and WL2 and the data storage element CAP, which may deteriorate the leakage current of the memory cell MC. The deterioration in the leakage current due to the high electric field may be accelerated as the channel CH becomes thinner.

As Comparative Example 2, when the first and second horizontal conductive lines WL1 and WL2 are formed of only a low work function material, the threshold voltage of the switching element TR may be reduced due to the low work function, thereby generating the leakage current.

According to one embodiment of the present invention, since each of the first and second horizontal conductive lines WL1 and WL2 of the horizontal conductive line DWL has a triple electrode structure, leakage current may be improved. Accordingly, refresh characteristics of the memory cell MC may be secured, which makes it possible to reduce power consumption.

Also, according to another embodiment of the present invention, since each of the first and second horizontal conductive lines WL1 and WL2 of the horizontal conductive line DWL has a triple electrode structure, even though the thickness of the channel CH is reduced for high integration, it may be relatively advantageous for increasing the electric field, which makes it possible to stack a high number of layers.

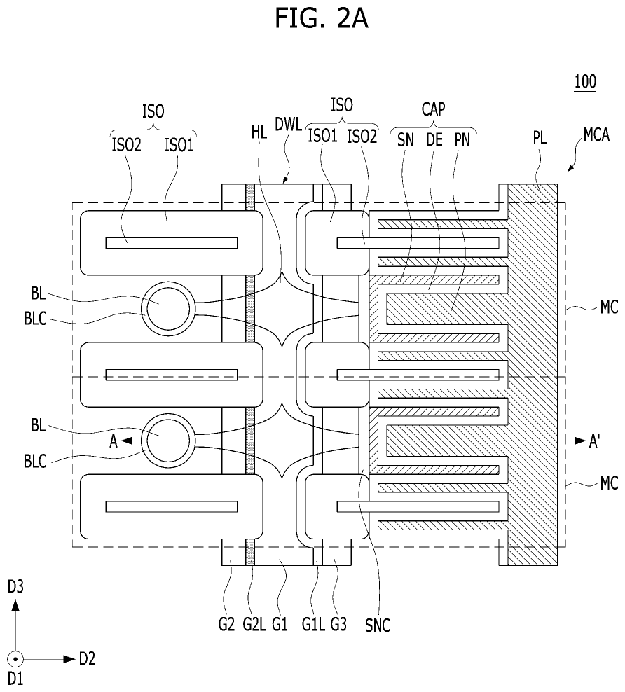

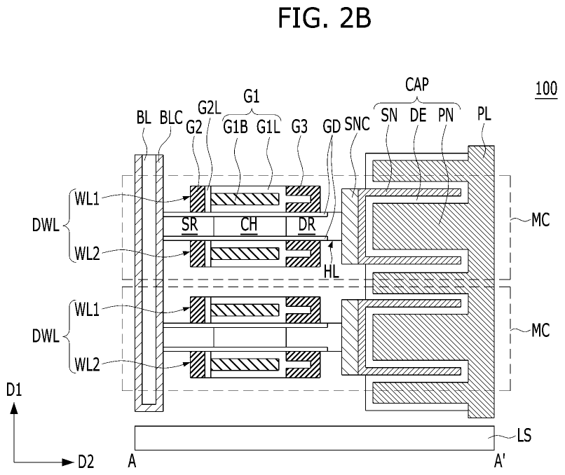

FIG. 2A is a schematic plan view illustrating a semiconductor device 100 in accordance with another embodiment of the present invention. FIG. 2B is a cross-sectional view taken along a line A-A′ shown in FIG. 2A.

Referring to FIGS. 2A and 2B, the semiconductor device 100 may include a lower structure LS and a memory cell array MCA. The memory cell array MCA may include a 3D array of memory cells MC. The 3D array of the memory cells MC may include a column array of memory cells MC and a row array of memory cells MC. The column array of the memory cells MC may include a plurality of memory cells MC that are stacked in the first direction D1, and the row array of the memory cells MC may include a plurality of memory cells MC that are horizontally disposed in the third direction D3. According to some embodiments of the present invention, cell dielectric layers may be disposed between the memory cells MC that are stacked in the first direction D1. Isolation layers ISO may be disposed between the memory cells MC that are disposed adjacent to each other in the third direction D3. The isolation layer ISO may include a first isolation material ISO1 and a second isolation material ISO2. The first isolation material ISO1 may include silicon oxide, and the second isolation material ISO2 may include silicon carbon oxide (SiCO). The memory cell array MCA may be disposed over the lower structure LS.

Each memory cell MC may include a vertical conductive line BL, a switching element TR, and a data storage element CAP. Each switching element TR may be a transistor, and it may include a horizontal layer HL, a gate dielectric layer GD, and a horizontal conductive line DWL. Each horizontal layer HL may include a first doped region SR, a second doped region DR, and a channel CH between the first doped region SR and the second doped region DR. Each horizontal conductive line DWL may include a pair of a first horizontal conductive line WL1 and a second horizontal conductive line WL2. Each of the first horizontal conductive line WL1 and the second horizontal conductive line WL2 may include a first work function electrode G1, a second work function electrode G2, and a third work function electrode G3. Each data storage element CAP may include a first electrode SN, a second electrode PN, and a dielectric layer DE between the first electrode SN and the second electrode PN.

The column array of the memory cells MC may include a plurality of switching elements TR that are stacked in the first direction D1, and the row array of the memory cells MC may include a plurality of switching elements TR that are disposed horizontally in the third direction D3.

The horizontal layers HL may be stacked over the lower structure LS in the first direction D1, and the horizontal layers HL may be spaced apart from the lower structure LS to extend in the second direction D2 that is parallel to the surface of the lower structure LS.

The vertical conductive line BL may extend in the first direction D1 which is perpendicular to the surface of the lower structure LS to be coupled to first-side ends of the horizontal layers HL.

The data storage elements CAP may be coupled to second-side ends of the horizontal layers HL, respectively.

The horizontal conductive lines DWL may be stacked over the lower structure LS in the first direction D1, and the horizontal conductive lines DWL may be spaced apart from the lower structure LS to extend in the third direction D3 which is parallel to the surface of the lower structure LS.

The second electrodes PN of the data storage elements CAP may be coupled to a common plate PL. The horizontal layers HL of the switching elements TR disposed horizontally in the third direction D3 may share one horizontal conductive line DWL. The horizontal layers HL of the switching elements TR disposed horizontally in the third direction D3 may be coupled to different vertical conductive lines BL. The switching elements TR stacked in the first direction D1 may share one vertical conductive line BL. The switching elements TR disposed horizontally in the third direction D3 may share one horizontal conductive line DWL.

The lower structure LS may include a semiconductor substrate or a peripheral circuit unit. The lower structure LS may be disposed at a lower level than the memory cell array MCA. This may be referred to as a COP (Cell-Over-Peripheral) structure. The peripheral circuit unit may include at least one control circuit for driving the memory cell array MCA. The at least one control circuit of the peripheral circuit unit may include for example an N-channel transistor, a P-channel transistor, a CMOS circuit, or a combination thereof. The at least one control circuit of the peripheral circuit unit may include for example an address decoder circuit, a read circuit, a write circuit, and the like. The at least one control circuit of the peripheral circuit unit may include for example a planar channel transistor, a recess channel transistor, a buried gate transistor, a fin channel transistor (FinFET), and the like.

In one example, the peripheral circuit unit may include sub-word line drivers and a sense amplifier. The horizontal conductive lines DWL may be coupled to the sub-word line drivers. The vertical conductive line BL may be coupled to the sense amplifier.

According to another embodiment of the present invention, the peripheral circuit unit may be disposed at a higher level than the memory cell array MCA. This may be referred to as a POC (Peripheral-Over-Cell) structure.

The memory cell array MCA may include horizontal conductive lines DWL that are stacked in the first direction D1. Each of the horizontal conductive lines DWL may include a pair of a first horizontal conductive line WL1 and a second horizontal conductive line WL2.

Each of the first and second horizontal conductive lines WL1 and WL2 may include a first work function electrode G1, a second work function electrode G2, and a third work function electrode G3. The first work function electrode G1, the second work function electrode G2, and the third work function electrode G3 may be horizontally disposed in the second direction D2. The first work function electrode G1, the second work function electrode G2, and the third work function electrode G3 may be parallel to each other while directly contacting each other. The second work function electrode G2 may be disposed adjacent to (or otherwise between the first work function electrode G1 and) the vertical conductive line BL, and the third work function electrode G3 may be disposed adjacent to (or otherwise between the first work function electrode G1 and) the data storage element CAP. In one embodiment, the first work function electrode G1, the second work function electrode G2, and the third work function electrode G3 may be formed of different work function materials, although second work function electrode G2 and third work function electrode G3 may be formed from the same work function material. The first work function electrode G1 may have a higher work function than the second and third work function electrodes G2 and G3. The first work function electrode G1 may include a high work function material. The first work function electrode G1 may have a work function which is higher than the mid-gap work function of silicon. The second and third work function electrodes G2 and G3 may include a low work function material. The second and third work function electrodes G2 and G3 may have a lower work function than a mid-gap work function of silicon. In other words, the high work function material may have a work function which is higher than approximately 4.5 eV, and the low work function material may have a work function which is lower than approximately 4.5 eV.

The first work function electrode G1 may include a metal-based material, and the second and third work function electrodes G2 and G3 may include a semiconductor material. The second and third work function electrodes G2 and G3 may include doped polysilicon that is doped with an N-type dopant. The first work function electrode G1 may include a metal, a metal nitride, or a combination thereof. The first work function electrode G1 may include for example tungsten, titanium nitride, or a combination thereof. A barrier material may be further formed between the second and third work function electrodes G2 and G3 and the first work function electrode G1.

The first work function electrode G1 may have a greater volume than the second and third work function electrodes G2 and G3, and accordingly, the horizontal conductive line DWL may have a lower resistance when first work function electrode G1 has a greater volume. The first work function electrodes G1 of the first and second horizontal conductive lines WL1 and WL2 may vertically overlap with each other in the first direction D1 with the horizontal layer HL interposed therebetween. The second and third work function electrodes G2 and G3 of the first and second horizontal conductive lines WL1 and WL2 may vertically overlap with each other in the first direction D1 with the horizontal layer HL interposed between the first and second horizontal conductive lines WL1 and WL2. The overlapping area between the first work function electrode G1 and the horizontal layer HL may be greater than the overlapping area between the second and third work function electrodes G2 and G3 and the horizontal layer HL. The second and third work function electrodes G2 and G3 and the first work function electrode G1 may extend in the third direction D3, and the second and third work function electrodes G2 and G3 and the first work function electrode G1 may directly contact.

Each of the first and second horizontal conductive lines WL1 and WL2 of the horizontal conductive line DWL may have a Polysilicon Metal Polysilicon (PMP) structure where WL1 and WL2 are horizontally disposed in the second direction D2. The first work function electrode G1 may be a ‘TiN/W stack’, and the second and third work function electrodes G2 and G3 may be doped polysilicon that is doped with an N-type dopant.

The first work function electrode G1 of the horizontal conductive line DWL may include a stack in which a first barrier layer G1L and a bulk layer G1B are sequentially stacked, and may further include a second barrier layer G2L that is disposed between the first work function electrode G1 and the second work function electrode G2. The first and second barrier layers G1L and G2L may include for example titanium nitride, tantalum nitride, tungsten nitride, or molybdenum nitride.

The first barrier layer G1L may include a continuous material extending in the third direction D3, and the second barrier layer G2L may include a discontinuous material that is cut by the isolation layer ISO. The first barrier layer G1L may extend while simultaneously contacting the third work function electrodes G3 and the isolation layer ISO. The second barrier layer G2L may be disposed between the isolation layers ISO that are disposed in the third direction D3.

As described above, each of the first and second horizontal conductive lines WL1 and WL2 may have a triple electrode structure including first, second, and third work function electrodes G1, G2, and G3. The horizontal conductive line DWL may include a pair of first work function electrodes G1, and a pair of first work function electrodes G1, a pair of second work function electrodes G2, and a pair of third work function electrodes G3 extending in the third direction D3 crossing the horizontal layer HL with the horizontal layer HL interposed therebetween.

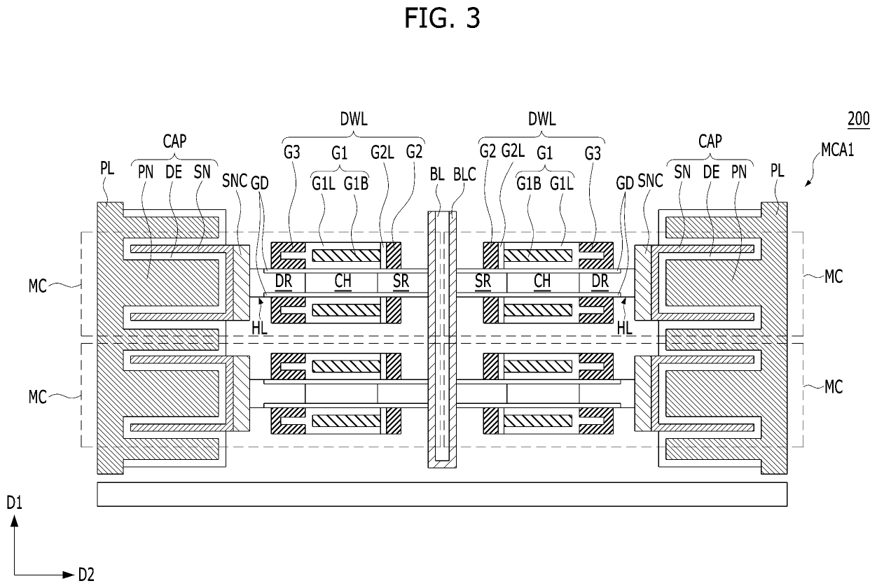

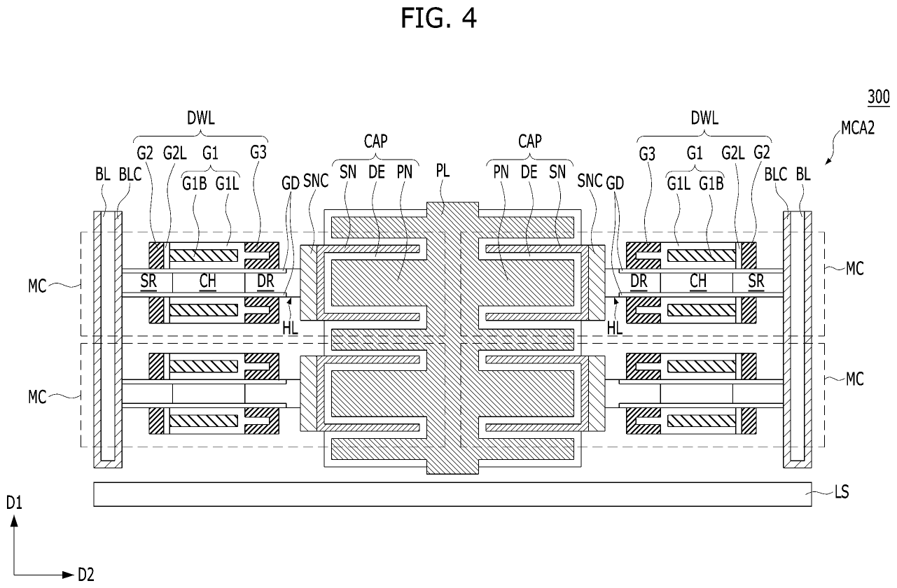

FIGS. 3 and 4 are schematic cross-sectional views illustrating semiconductor devices in accordance with other embodiments of the present invention. As for the constituent elements of FIGS. 3 and 4 also appearing in FIGS. 1A, 1B, 2A and 2B, detailed descriptions on them will be omitted.

Referring to FIG. 3, a semiconductor device 200 may include a memory cell array MCA1, and the memory cell array MCA1 may have a mirror-type structure sharing a vertical conductive line BL. Referring to FIG. 4, a semiconductor device 300 may include a memory cell array MCA2, and the memory cell array MCA2 may have a mirror-type structure sharing a common plate PL.

The memory cell arrays MCA1 and MCA2 illustrate a three-dimensional memory cell array including four memory cells MC. Each memory cell MC may include a switching element TR including a horizontal layer HL and a horizontal conductive line DWL, a vertical conductive line BL, and a data storage element CAP. The horizontal conductive line DWL may include a first work function electrode G1, a second work function electrode G2, and a third work function electrode G3. The data storage element CAP may include a first electrode SN, a dielectric layer DE, and a second electrode PN. A gate dielectric layer GD may be disposed between the horizontal conductive line DWL and the horizontal layer HL. As illustrated in FIGS. 1C and 2B and as also shown in FIG. 3 and FIG. 4, the horizontal layer HL may include a first doped region SR, a channel CH, and a second doped region DR. In the horizontal conductive line DWL, the first work function electrode G1 may include a high work function material, and the second work function electrode G2 and the third work function electrode G3 may include a low work function material. The first work function electrode G1 may include a metal-based material, and the second and third work function electrodes G2 and G3 may include a semiconductor material. As illustrated in FIG. 1C and also as shown in FIG. 4, the first work function electrode G1 of the horizontal conductive line DWL may include a first barrier layer G1L and a bulk layer G1B. The horizontal conductive line DWL may further include a second barrier layer G2L between the first work function electrode G1 and the second work function electrode G2.

The horizontal layers HL of the memory cells MC that are adjacent to each other in the first direction D1 may contact one vertical conductive line BL. The data storage elements CAP may be respectively coupled to the horizontal layers HL.

The semiconductor devices 200 and 300 may further include a lower structure LS below the memory cell array MCA1, and the lower structure LS may include a peripheral circuit unit. The peripheral circuit unit may be disposed at a lower level than the memory cell array MCA1. This may be referred to as a COP (Cell-Over-Peripheral) structure. The peripheral circuit unit may include at least one control circuit for driving the memory cell array MCA1.

According to another embodiment of the present invention, the peripheral circuit unit may be disposed at a higher level than the memory cell array MCA1. This may be referred to as a POC structure.

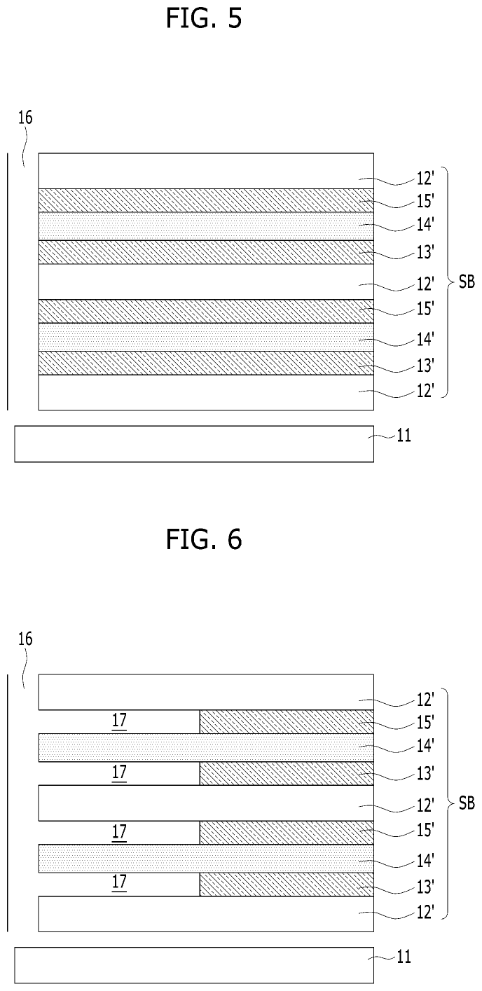

FIGS. 5 to 24 illustrate an example of a method for fabricating a semiconductor device in accordance with various embodiments of the present invention.

Referring to FIG. 5, a stack body SB may be formed over the lower structure 11. The stack body SB may include a plurality of sub-stacks that are alternately stacked. Each sub-stack may include a dielectric layer 12′, a first sacrificial layer 13′, a semiconductor layer 14′, and a second sacrificial layer 15′ that are stacked in the mentioned order. The dielectric layers 12′ may include silicon oxide, and the first and second sacrificial layers 13′ and 15′ may include silicon nitride. The semiconductor layer 14′ may include a semiconductor material or an oxide semiconductor material. The semiconductor layer 14′ may include for example monocrystalline silicon, polysilicon, or indium gallium zinc oxide (IGZO). As described in the foregoing embodiments, when memory cells are stacked, the stack body SB may be stacked a plurality of times.

Subsequently, a first opening 16 may be formed by etching a portion of the stack body SB. The first opening 16 may extend vertically from the surface of the lower structure 11. Before the first opening 16 is formed, as illustrated in FIGS. 2A and 2B, the stack body SB may be patterned on the basis of a memory cell unit.

Referring to FIG. 6, recesses 17 may be formed by selectively etching the first and second sacrificial layers 13′ and 15′ through the first opening 16. A portion of the semiconductor layer 14′ may be exposed by the recesses 17. The recesses 17 may be disposed between the dielectric layers 12′.

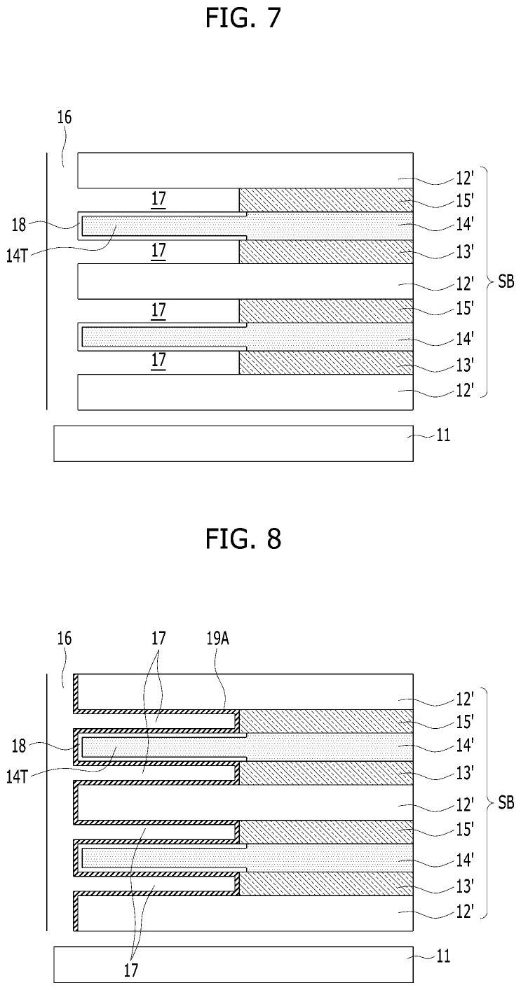

Referring to FIG. 7, a gate dielectric layer 18 may be formed over the exposed portion of the semiconductor layer 14′. The gate dielectric layer 18 may include for example a silicon oxide, a silicon nitride, a metal oxide, a metal oxynitride, a metal silicate, a high-k material, a ferroelectric material, an antiferroelectric material, or a combination thereof. The gate dielectric layer 18 may include for example SiO₂, Si₃N₄, HfO₂, Al₂O₃, ZrO₂, AION, HfON, HfSIO, HfSION, or combinations thereof.

According to one embodiment of the present invention, the gate dielectric layer 18 may be formed by an oxidation process, and a portion 14T of the semiconductor layer 14′ may be thinned. The thinned portion 14T of the semiconductor layer 14′ may be referred to as a thin body 14T.

Referring to FIG. 8, a first work function material 19A may be conformally formed in the recesses 17. The first work function material 19A may conformally cover the recesses 17 over the gate dielectric layer 18. The first work function material 19A may include a conductive material. The first work function material 19A may have a work function that is lower than a mid-gap work function of silicon. In one example, the first work function material 19A may include doped polysilicon that is doped with an N-type dopant. The N-type dopant may include phosphorus (P) or arsenic (As).

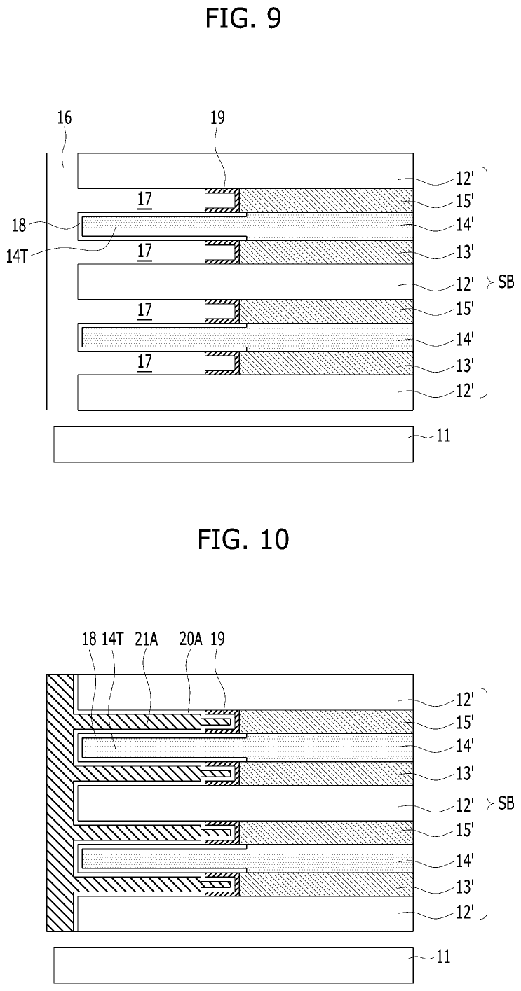

Referring to FIG. 9, a first low work function electrode 19 may be formed in the recesses 17. To form the first low work function electrode 19, the first work function material 19A may be selectively etched. For example, a wet etching process may be performed on the first work function material 19A.

A pair of first low work function electrodes 19 may be formed with the thin body 14T of the semiconductor layer 14′ interposed between the pairs. The first low work function electrode 19 may have a cup shape or a bent shape.

Referring to FIG. 10, a first barrier material 20A and a second work function material 21A may be sequentially formed over the first low work function electrode 19 to gap-fill the remaining portions of the recesses 17. The first barrier material 20A may include a metal-based material. The first barrier material 20A may include a metal nitride. The second work function material 21A may have a work function that is higher than the mid-gap work function of silicon. The second work function material 21A may have a higher work function than the first low work function electrode 19. The second work function material 21A may have a lower resistance than the first low work function electrode 19. The second work function material 21A may include a metal-based material. The second work function material 21A may include a metal nitride, a metal, or a combination thereof. The second work function material 21A may include titanium nitride, tungsten, or a combination thereof. In the stack of the first barrier material 20A and the second work function material 21A, titanium nitride and tungsten may be sequentially stacked.

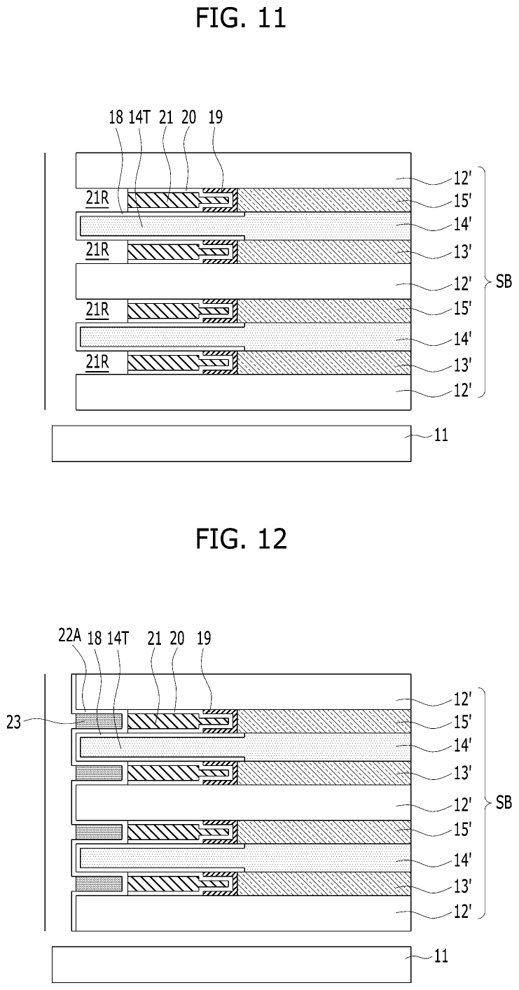

Referring to FIG. 11, a first barrier layer 20 and a high work function electrode 21 may be formed in the recesses 17. In order to form the first barrier layer 20 and the high work function electrode 21, the first barrier material 20A and the second work function material 21A may be selectively etched. For example, the first barrier material 20A and the second work function material 21A may be dry-etched or wet-etched, individually.

The first barrier layer 20 may have a cup shape or a bent shape. The high work function electrode 21 may be disposed on the inner surface of the first barrier layer 20. The high work function electrode 21 may be disposed adjacent to first side surfaces of the first low work function electrode 19 with the first barrier layer 20 interposed therebetween. The high work function electrode 21 may have a higher work function than the first low work function electrode 19. The high work function electrode 21 may include a metal-based material. For example, the high work function electrode 21 may include titanium nitride, tungsten, or a combination thereof.

A pair of high work function electrodes 21 may be formed with the thin body 14T of the semiconductor layer 14′ interposed therebetween. The first low work function electrodes 19 and the high work function electrodes 21 may partially fill the recesses 17. After the high work function electrodes 21 are formed, first sacrificial recesses 21R may be defined.

Referring to FIG. 12, a second barrier material 22A may be formed in the first sacrificial recesses 21R. The second barrier material 22A may conformally cover the first sacrificial recesses 21R. The second barrier material 22A may include a metal-based material. The second barrier material 22A may include a metal nitride. The second barrier material 22A may include titanium nitride.

A sacrificial barrier 23 may be formed over the second barrier material 22A. The sacrificial barrier 23 may include polysilicon. To form the sacrificial barrier 23, polysilicon deposition and etch-back may be performed.

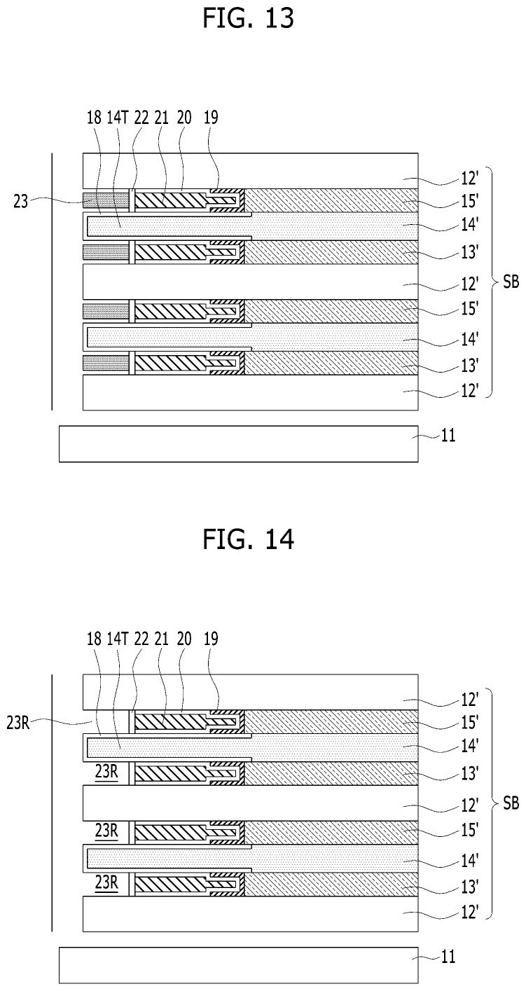

Referring to FIG. 13, the second barrier material 22A may be selectively etched using the sacrificial barrier 23 as an etch stopper. Accordingly, the second barrier layer 22 contacting the high work function electrode 21 and the first barrier layer 20 may be formed.

Referring to FIG. 14, the sacrificial barrier 23 may be removed. As the sacrificial barrier 23 is removed, second sacrificial recesses 23R exposing the second barrier layer 22 may be defined.

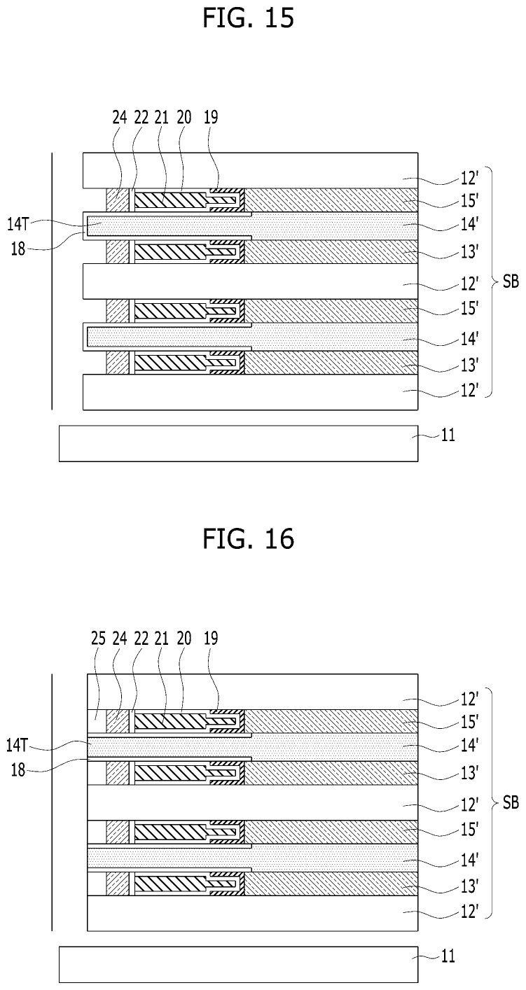

Referring to FIG. 15, a second low work function electrode 24 contacting the second barrier layer 22 may be formed. Forming the second low work function electrode 24 may include depositing a third work function material on the second barrier layer 22 to fill the second sacrificial recesses 23R, and etching the third work function material to form the second low work function electrode 24. The second low work function electrode 24 may include doped polysilicon that is doped with an N-type dopant. The first low work function electrode 19 and the second low work function material 24 may be of the same material.

A pair of second low work function electrodes 24 may be formed with the thin body 14T of the semiconductor layer 14′ interposed therebetween.

As a result of a series of processes as described above, a pair of first low work function electrodes 19, a pair of high work function electrodes 21, and a pair of second low work function electrodes 24 may be formed with the thin body 14T of the semiconductor layer 14′ interposed therebetween. The pair of the first low work function electrodes 19, the pair of the high work function electrodes 21, and the pair of the second low work function electrodes 24 may be double-structured horizontal conductive lines DWL. The first work function electrodes G1 as illustrated in FIGS. 1A to 3 may correspond to the high work function electrodes 21, and the second work function electrodes G2 as illustrated in FIGS. 1A to 3 may correspond to the second low work function electrodes 24. The third work function electrodes G3 as illustrated in FIGS. 1A to 3 may correspond to the first low work function electrode 19. The high work function electrode 21 may be parallel to the first low work function electrode 19 but may have a higher work function than the first low work function electrode 19. The second low work function electrode 24 may be parallel to the high work function electrode 19, but may have a lower work function than the high work function electrode 19. The first barrier layer 20 may be disposed between the first low work function electrode 19 and the high work function electrode 21, and the second barrier layer 22 may be disposed between the second low work function electrode 19 and the high work function electrode 21. The first and second barrier layers 20 and 22 may prevent the diffusion between the high work function electrode 21 and the first and second low work function electrodes 19 and 24.

The first low work function electrode 19 may have a bent shape or a cup shape. The first work function electrode 19 may include an inner surface covering the first barrier layer 20. The first work function electrode 19 may include a bent low work function material. The first barrier layer 20 may surround a portion of the high work function electrode 21. The first barrier layer 20 may have a bent shape or a cup shape. The first barrier layer 20 may include an inner surface covering the high work function electrode 21 and an outer surface contacting the first low work function electrode 19. The first barrier layer 20 may have a protruding shape filling the inner surface of the first low work function electrode 19. The second barrier layer 22 may have a vertical or flat shape.

The first low work function electrode 19, the high work function electrode 21, and the second low work function electrode 24 may have a triple work function electrode structure, and may form the horizontal conductive line DWL as illustrated in FIGS. 1A to 2B.

Referring to FIG. 16, first capping layers 25 may be formed on the side surfaces of the second low work function electrode 24. The first capping layers 25 may include silicon oxide or silicon nitride.

Subsequently, a portion of the gate dielectric layer 18 exposed by the first capping layers 25 may be etched to expose a first-side end of the thin body 14T of the semiconductor layer 14′.

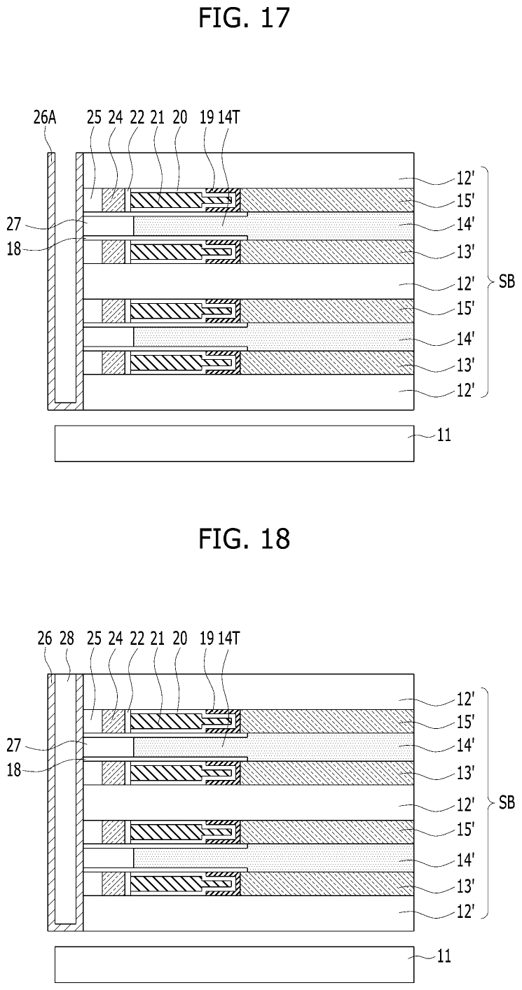

Referring to FIG. 17, a first contact node 26 may be formed to be coupled to the first-side end of the thin body 14T of the semiconductor layer 14′. The first contact node 26 may include polysilicon that is doped with an N-type impurity.

After the first contact node 26 is formed, heat treatment may be performed to form a first doped region 27 in the thin body 14T of the semiconductor layer 14′. The first doped region 27 may include impurities diffused from the first contact node 26. According to another embodiment of the present invention, the first doped region 27 may be formed by a process of doping an impurity.

According to another embodiment of the present invention, the bottom portion of the first contact node 26 may be partially cut.

Referring to FIG. 18, a vertical conductive line 28 may be formed over the first contact node 26. The vertical conductive line 28 may fill the first opening 16. The vertical conductive line 28 may include titanium nitride, tungsten, or a combination thereof.

According to another embodiment of the present invention, before the vertical conductive line 23 is formed, a first ohmic contact coupled to the first-side end of the thin body 14T of the semiconductor layer 14′ may be formed. The first ohmic contact may include a metal silicide. For example, a metal silicide may be formed by sequentially performing a process of depositing a metal layer and performing an annealing process, and the unreacted metal layer may be removed. The metal silicide may be formed by reacting silicon of the thin body 14T of the semiconductor layer 14′ with the metal layer.

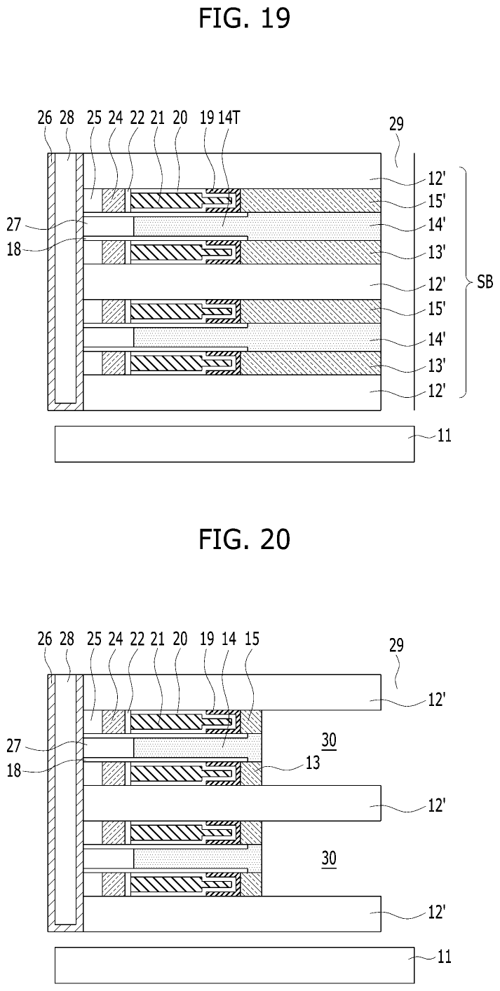

Referring to FIG. 19, a second opening 29 may be formed by etching another portion of the stack body SB. The second opening 29 may extend vertically from the surface of the lower structure 11.

Referring to FIG. 20, the first and second sacrificial layers 13′ and 15′ and the semiconductor layer 14′ may be selectively recessed through the second opening 29. Accordingly, wide openings 30 may be formed between the dielectric layers 12′. The semiconductor layer 14′ including the thin body 14T may remain as the horizontal layer 14 as indicated by a reference numeral 14, and a second-side end of the horizontal layer 14 may be exposed by the wide opening 30. Second capping layers 13 and 15 may be formed on the side surfaces of the first low work function electrode 19 by the selective recess process of the first and second sacrificial layers 13′ and 15′, respectively.

The horizontal layer 14 may be thinner than the first low work function electrodes 19, the high work function electrodes 21, and the second low work function electrodes 24. The horizontal layer 14 may be referred to as a thin-body active layer.

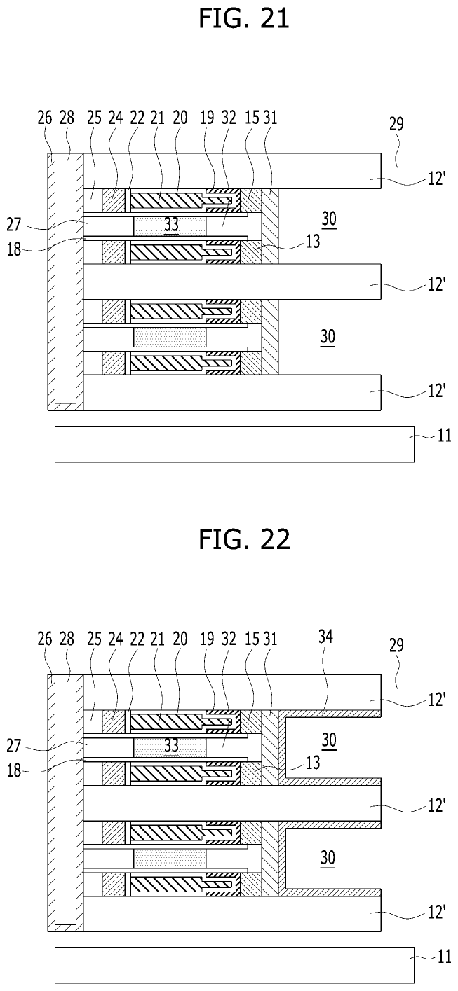

Referring to FIG. 21, a second contact node 31 may be formed. The second contact node 31 may include polysilicon containing an impurity. Forming the second contact node 31 may include forming doped polysilicon over the wide opening 30 and etching the doped polysilicon.

Subsequently, a second doped region 32 may be formed. The second doped region 32 may diffuse the impurity from the second contact node 31 to the second-side end of the horizontal layer 14 by performing a subsequent heat treatment. Accordingly, a second doped region 32 may be formed in the second-side end of the horizontal layer 14. A channel 33 may be defined between the first doped region 27 and the second doped region 32. The first doped region 27, the channel 33, and the second doped region 32 may correspond to the first doped region SR, the channel CH, and the second doped region DR shown in FIG. 1B.

According to another embodiment of the present invention, after the wide opening 30 is formed, the second doped region 32 may be formed in the second-side end of the horizontal layer 14. The second doped region 32 may be formed by an impurity doping process.

According to another embodiment of the present invention, a second ohmic contact coupled to the second-side end of the horizontal layer 14 may be formed. The second ohmic contact may include a metal silicide. For example, a metal silicide may be formed by sequentially performing a metal layer deposition process and an annealing process, and the unreacted metal layer may be removed. The metal silicide may be formed by reacting the silicon of the horizontal layer 14 with the metal layer.

Referring to FIG. 22, a first electrode 34 contacting the respective second-side ends of the horizontal layers 14 may be formed. To form the first electrode 34, a process of depositing a conductive material and an etch-back process may be performed. The first electrode 34 may include titanium nitride. The first electrode 34 may be in the shape of a horizontally oriented cylinder.

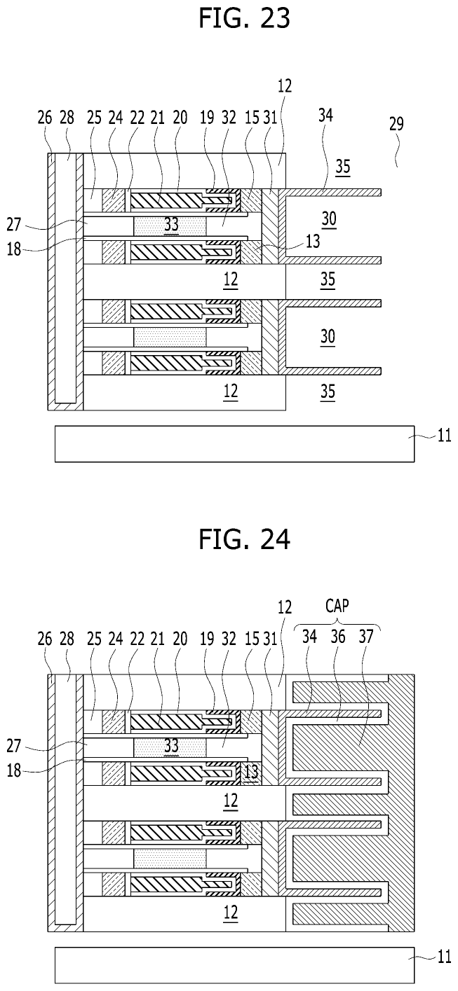

Referring to FIG. 23, the dielectric layers 12′ may be partially recessed 35. Accordingly, the outer walls of the first electrodes 34 may be exposed. The remaining dielectric layers 12 may contact the horizontal conductive line DWL. The remaining dielectric layers 12 may be referred to as cell dielectric layers or cell isolation layers.

Referring to FIG. 24, a dielectric layer 36 and a second electrode 37 may be sequentially formed over the first electrodes 34. The first electrode 34, the dielectric layer 36, and the second electrode 37 may become a data storage element CAP.

According to another embodiment of the present invention, the horizontal conductive line DWL may have a single structure. For example, the horizontal conductive line of the single structure may include one horizontal conductive line between the first horizontal conductive line WL1 and the second horizontal conductive line WL2. The single-structured horizontal conductive line may include a triple work function structure.

According to one embodiment of the present invention, memory cells may be highly integrated by forming a word line of a triple electrode structure.

According to one embodiment of the present invention, leakage current may be improved by forming a word line of a triple electrode structure. Accordingly, refresh characteristics may be secured, which may reduce power consumption.

The disclosed embodiments of the present invention are relatively advantageous in the manner of increasing an electric field formed when the thickness of a channel is reduced for the purpose of higher device integration. Therefore, the technology of the present invention is advantageous for higher device integration when forming a higher number of stacked layers.

According to one embodiment of the present invention, since a barrier layer is formed between a high work function electrode and a low work function electrode, electrical characteristics of a word line may be improved.

According to one embodiment of the present invention, low power consumption and high integration of 3D memory cells may be realized.

While the present invention has been described with respect to the specific embodiments, it will be apparent to those skilled in the art that various changes and modifications may be made without departing from the spirit and scope of the invention as disclosed herein.

What is claimed is:

1. A semiconductor device, comprising:
a lower structure;
a horizontal layer spaced apart from the lower structure and extending in a direction parallel to the lower structure;
a vertical conductive line extending in a direction perpendicular to the lower structure and coupled to a first-side end of the horizontal layer;
a data storage element coupled to a second-side end of the horizontal layer; and
a horizontal conductive line extending in a direction crossing the horizontal layer,
wherein the horizontal conductive line includes:
a first work function electrode;
a second work function electrode disposed adjacent to the vertical conductive line and having a lower work function than the first work function electrode;
a third work function electrode disposed adjacent to the data storage element and having a lower work function than the first work function electrode;
a first barrier layer between the first work function electrode and the third work function electrode; and
a second barrier layer between the first work function electrode and the second work function electrode.

2. The semiconductor device of claim 1, wherein the second and third work function electrodes have a work function that is lower than a mid-gap work function of silicon, and
the first work function electrode has a work function that is higher than the mid-gap work function of silicon.

3. The semiconductor device of claim 1, wherein the second and third work function electrodes include doped polysilicon that is doped with an N-type dopant.

4. The semiconductor device of claim 1, wherein the first work function electrode includes a metal-based material.

5. The semiconductor device of claim 1, wherein the first work function electrode includes a metal, a metal nitride, or a combination thereof.

6. The semiconductor device of claim 1, wherein the first work function electrode has a greater volume than the second and third work function electrodes.

7. The semiconductor device of claim 1, wherein each of the first, second, and third work function electrodes vertically overlaps with the horizontal layer.

8. The semiconductor device of claim 1, wherein the second work function electrode and the third work function electrode have the same work function.

9. The semiconductor device of claim 1, wherein the horizontal layer has a thickness that is smaller than thicknesses of the first, second, and third work function electrodes.

10. The semiconductor device of claim 1, wherein the horizontal layer includes a monocrystalline semiconductor material, a polycrystalline semiconductor material, or an oxide semiconductor material.

11. The semiconductor device of claim 1, wherein the horizontal layer includes:
a first doped region coupled to the vertical conductive line;
a second doped region coupled to the data storage element; and
a channel between the first doped region and the second doped region.

12. The semiconductor device of claim 1, wherein the horizontal conductive line includes a double structure of horizontal conductive lines that face each other with the horizontal layer interposed therebetween.

13. The semiconductor device of claim 1, wherein the data storage element includes a capacitor, and
the capacitor includes a cylindrical first electrode, a second electrode, and a dielectric layer between the first electrode and the second electrode.

14. The semiconductor device of claim 1, further comprising:
a first contact node between the vertical conductive line and the first-side end of the horizontal layer; and
a second contact node between the data storage element and the second-side end of the horizontal layer.

15. The semiconductor device of claim 1, wherein the first and second barrier layers include a metal nitride.
